(19) United States
(12) Patent Application Publication
(10) Pub. No.: US 2015/0194572 A1
(43) Pub. Date: Jul. 9, 2015

(54) LIGHT-EMITTING DIODE PACKAGE

(71) Applicant: Samsung Display Co., Ltd., Yongin-City (KR)

(72) Inventors: Myung Seok KWON, Seongnam-si (KR); Young Keun LEE, Suwon-si (KR); Young Min PARK, Hwaseong-si (KR)

(73) Assignee: Samsung Display Co., Ltd., Yongin-City (KR)

(21) Appl. No.: 14/271,514

(22) Filed: May 7, 2014

(30) Foreign Application Priority Data
Jan. 3, 2014 (KR) 10-2014-0000716

(51) Int. Cl. H01L 33/20; H01L 33/52; H01L 33/62; H01L 33/48; H01L 33/60

(52) U.S. Cl. CPC H01L 33/20; H01L 33/483; H01L 33/60; H01L 33/62; H01L 33/52

(57) ABSTRACT

A light-emitting diode (“LED”) package includes a substrate, an LED chip on the substrate, and a light exit surface adjuster. The light exit surface adjuster includes a light-transmitting surface which transmits light and a light-blocking surface which is around the light-transmitting surface and blocks the light. The LED chip is between the light exit surface adjuster and the substrate, and an overlap area between the LED chip and the light-transmitting surface is smaller than an overall area of the LED chip.

This application claims priority to Korean Patent Application No. 10-2014-0000716 filed on Jan. 3, 2014, and all the benefits accruing therefrom under 35 U.S.C. §119, the disclosure of which is incorporated herein by reference in its entirety.

### BACKGROUND OF THE INVENTION

1. Field

The invention relates to a light-emitting diode (“LED”) package.

2. Description of the Related Art

Liquid crystal displays (“LCDs”) are of great importance in information display technology. An LCD includes two glass substrates, and liquid crystal inserted between the two glass substrates. The LCD displays information by providing power to electrodes disposed on and under the glass substrates and converts the power into light using the liquid crystal.

The LCD includes a liquid crystal panel which is a light-receiving device that does not self-emit light and displays an image by controlling transmittance of light received from an external source. Therefore, the LCD includes a device for generating and irradiating light to the liquid crystal panel, that is, a backlight unit.

A light-emitting diode (“LED”) is drawing attention as a light source of a backlight unit of an LCD. The LED is a semiconductor light-emitting device that emits light when an electric current flows therethrough. Due to a relatively long life, low power consumption and fast response speed and superior initial driving characteristics, LEDs are widely used as backlight units of lighting devices, electronic display boards and displays, and the like and their field of application is expanding gradually.

### SUMMARY

To enable a viewer to watch an image with uniform luminance on a display device such as a liquid crystal display (“LCD”), light emitted from a backlight unit of the display device should be provided to a display panel of the display device at a uniform luminance level across the whole surface of the display panel. To this end, a difference between bright and dark portions of light emitted from a light source of the backlight unit should be reduced. Therefore, research is being conducted to reduce the difference between bright and dark portions that can be created in a self-emitting light source when a light-emitting diode (“LED”) is used as the light source in the backlight unit.

One or more exemplary embodiment of the invention provides a LED package which can reduce a difference between bright and dark portions caused by light emitted from corners of a light-emitting source including the LED package.

One or more exemplary embodiment of the invention also provides an LED package of which a light source thereof has superior appearance.

However, the invention is not restricted to the exemplary embodiments set forth herein. The above and other features of the invention will become more apparent to one of ordinary skill in the art to which the invention pertains by referencing the detailed description of the invention given below.

According to an exemplary embodiment of the invention, there is provided a LED package including a substrate, an LED chip on the substrate, and a light exit surface adjuster including a light-transmitting surface which transmits light and a light-blocking surface which is around the light-transmitting surface and blocks the light. The LED chip is between the light exit surface adjuster and the substrate, and an overlap area between the LED chip and the light-transmitting surface is smaller than an overall area of the LED chip.

The light-transmitting surface may include a curved planar shape.

The light-transmitting surface may include a circular planar shape.

The light-transmitting surface may overlap the LED chip and be inscribed within edges of the LED chip.

The light transmitting surface may overlap the LED chip and be within edges of the LED chip.

The light exit surface adjuster may further include a support which contacts the light-blocking surface and is extended from the light-blocking surface and toward the substrate. The support may separate the light-transmitting surface and the light-blocking surface from the LED chip.

A groove may be defined in the substrate and at a portion thereof which contacts the support. The support may extend into and be coupled to the groove.

The LED package may further include a frame on the substrate and surrounding the light-blocking surface. A cavity may be defined in the frame and be open at an upper side of the frame.

The LED package may further include an encapsulant which fills the cavity and seals the LED chip and the light-transmitting surface in the cavity.

The frame may include a reflective material.

The LED package may further include a frame which is on the substrate, and a cavity defined in the frame and open at an upper side of the frame. The LED chip may be inside the cavity, and the frame may include a step at an inner side surface thereof and defining the cavity.

The light exit surface adjuster may be on the step.

The LED package may further include a first electrode and a second electrode which are electrically connected to the LED chip and face each other. The first electrode and the second electrode may be on the substrate, the LED chip may be on the first electrode and the second electrode, the first electrode and the second electrode respectively may include a first protruding surface and a second protruding surface which protrude upward from the substrate, and the light exit surface adjuster may be on the first protruding surface and the second protruding surface.

According to another exemplary embodiment of the invention, there is provided an LED package including a substrate, an LED chip on the substrate, and a light exit surface adjuster including a light-transmitting surface which transmits light and a light-blocking surface which is located around the light-transmitting surface and blocks the light. The LED chip is between the light exit surface adjuster and the substrate, and the light-blocking surface overlaps the LED chip.

The light-transmitting surface may include a circular planar shape.

The light-transmitting surface may overlap the LED chip and be inscribed within edges of the LED chip in a plan view.

According to another exemplary embodiment of the invention, there is provided an LED package including a substrate, an LED chip on the substrate, and a light-blocking material which covers the periphery of the LED chip to and blocks light emitted from the LED chip.

The light-blocking material may cover corners of the LED chip in the plan view.

An opening may be defined in the light-blocking material and having a curved planar shape in the plan view.

A circular opening may be defined in the light-blocking material, and the opening may be smaller than or equal to a size of a circle inscribed in the LED chip in the plan view.

### BRIEF DESCRIPTION OF THE DRAWINGS

The above and other features of the invention will become more apparent by describing in detail exemplary embodiments thereof with reference to the attached drawings, in which:

FIG. 1 is a cross-sectional view of an exemplary embodiment of a light-emitting diode (“LED”) package according to the invention;

FIG. 2 is a cross-sectional view of another exemplary embodiment of a LED package according to the invention;

FIG. 3 is a perspective view of an exemplary embodiment of a light exit surface adjuster according to the invention;

FIG. 4 is a top plan view of the light exit surface adjuster of FIG. 3 with reference to an LED chip therebelow;

FIG. 5 is a plan view of a modified exemplary embodiment of the light exit surface adjuster of FIG. 4 for which a light-transmitting surface is adjusted in size;

FIG. 6 is a plan view of another modified exemplary embodiment of the light exit surface adjuster of FIG. 4 for which a light-transmitting surface is adjusted in size;

FIG. 7 is a perspective view of another exemplary embodiment of a light exit surface adjuster according to the invention;

FIG. 8 is a top plan view of the light exit surface adjuster of FIG. 7 with reference to an LED chip therebelow;

FIG. 9 is a perspective view of still another exemplary embodiment of a light exit surface adjuster according to the invention;

FIG. 10 is a top plan view of the light exit surface adjuster of FIG. 9 with reference to an LED chip therebelow;

FIG. 11 is a perspective view of yet another exemplary embodiment of a light exit surface adjuster according to the invention;

FIGS. 12 through 17 are cross-sectional views of other exemplary embodiments of an LED package according to the invention;

FIG. 18 is a perspective view of still another exemplary embodiment of a light exit surface adjuster according to the invention;

FIG. 19 is a cross-sectional view of still another exemplary embodiment of an LED package according to the invention;

FIGS. 20 through 22 are perspective views of still other exemplary embodiments of a light exit surface adjuster according to the invention;

FIGS. 23 through 25 are cross-sectional views of still other exemplary embodiments of a LED package according to the invention;

FIG. 26 is a perspective view of still another exemplary embodiment of a light exit surface adjuster according to the invention; and

FIG. 27 is a cross-sectional view of still another exemplary embodiment of an LED package according to the invention.

### DETAILED DESCRIPTION

The features of the invention and methods for achieving the features will be apparent by referring to the exemplary embodiments described in detail with reference to the accompanying drawings. However, the invention is not limited to the exemplary embodiments disclosed hereinafter, but can be implemented in diverse forms. The matters defined in the description, such as the detailed construction and elements, are nothing but specific details provided to assist those of ordinary skill in the art in a comprehensive understanding of the invention, and the invention is only defined within the scope of the appended claims.

The term “on” that is used to designate that an element is on another element or located on a different layer or a layer includes both a case where an element is located directly on another element or a layer and a case where an element is located on another element via another layer or still another element. In the entire description of the invention, the same drawing reference numerals are used for the same elements across various figures. As used herein, connected may refer to elements being physically and/or electrically connected to each other. As used herein, the term “and/or” includes any and all combinations of one or more of the associated listed items.

Although the terms “first, second, and so forth” are used to describe diverse constituent elements, such constituent elements are not limited by the terms. The terms are used only to discriminate a constituent element from other constituent elements. Accordingly, in the following description, a first constituent element may be a second constituent element.

Spatially relative terms, such as “below,” “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “under” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the invention will be described with reference to the attached drawings.

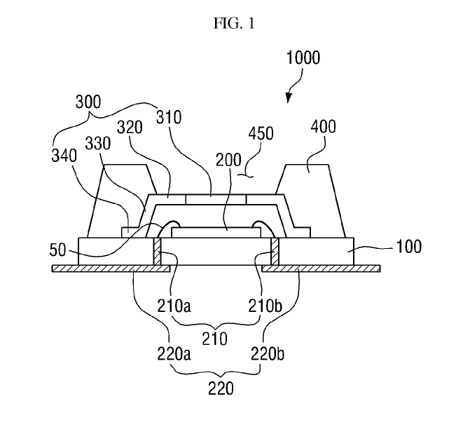

FIG. 1 is a cross-sectional view of an exemplary embodiment of a light-emitting diode (“LED”) package 1000 according to the invention.

Referring to FIG. 1, the LED package 1000 may include a substrate 100, an LED chip 200 disposed on the substrate 100, and a light exit surface adjuster 300. The light exit surface adjuster 300 may include a light-transmitting surface portion 310 through which transmits light, and a light-blocking surface portion 320 which is located around the light-transmitting surface portion 310 and blocks light. For convenience of description, light-transmitting surface portion and light-blocking surface portion may be otherwise referred to as a light-transmitting surface and light-blocking surface, respectively.

The LED chip 200 may be disposed between the light exit surface adjuster 300 and the substrate 100. An area of the LED chip 200 overlapped by the light-transmitting surface 310 of the light exit surface adjuster 300 may be smaller than a whole area of the LED chip 200, in a top plan view. The LED chip 200 may be a blue LED chip or an ultraviolet (“UV”) LED chip. The LED chip 200 may have a square planar shape. That is, in a top plan view of the LED package 1000 taken from the light exit surface adjuster 300 toward the substrate 100, the LED chip 200 may be square in shape.

The LED chip 200 may be electrically connected to electrodes 220 by lead frames 50, respectively. More specifically, each of the electrodes 220 may be disposed under the substrate 100 to be electrically connected to an external circuit (not shown) and receive signals from the external circuit. The electrodes 220 may be connected to the lead frames 50 of the LED chip 200 mounted on the substrate 100 by via holes 210a and 210b defined in the substrate 100, respectively. Therefore, the electrodes 220 and the lead frames 50 may include a metallic material having superior thermal conductivity, such as gold (Au), silver (Ag), or copper (Cu).

The light exit surface adjuster 300 may be disposed on the substrate 100, and the LED chip 200 may be disposed between the substrate 100 and the light exit surface adjuster 300. That is, the electrodes 220 may be disposed under the substrate 100, and the LED chip 200 and the light exit surface adjuster 300 may be stacked sequentially on (e.g., above) the substrate 100.

The light exit surface adjuster 300 may include the light-transmitting surface 310 through which transmits light and the light-blocking surface 320 which is located around the light-transmitting surface 310 and blocks light. A planar shape of the light exit surface adjuster 300 may be circular in the top plan view. The light-blocking surface 320 may be disposed at an outer part of the light exit surface adjuster 300, and the circular light-transmitting surface 310 may be disposed at an inner part of the light exit surface adjuster 300 (e.g., towards a center of the light exit surface adjuster 300.

The light-blocking surface 320 may include a light-blocking material. Alternatively, the light-blocking surface 320 may include disposing a separate light-blocking material to a base material or body of the light exit surface adjuster 300. The light-transmitting surface 310 may be located inside the light-blocking surface 320 and may include a light-transmitting material. In an exemplary embodiment, for example, the light-transmitting surface 310 may include transparent polymer resin or transparent glass or may be an empty space defined by portions of an element of the LED package, as will be described later.

The light exit surface adjuster 300 will be described in greater detail later.

The LED package 1000 may further include a frame 400 (otherwise referred to herein as a molding or molded frame) which is disposed on the substrate 100 to surround the light-blocking surface 320 of the light exit surface adjuster 300. The molding frame 400 may include a cavity 450 defined therein which is open at an upper side thereof. The cavity 450 exposes the light exit surface adjuster 300 to outside the LED package 1000.

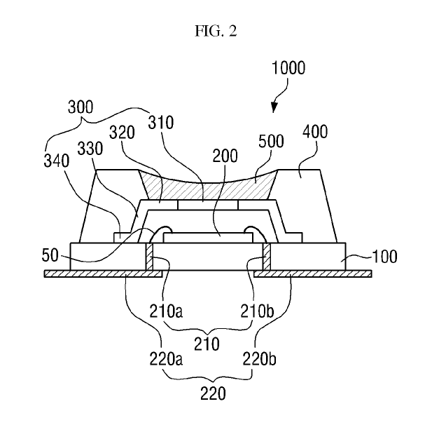

More specifically, the molding frame 400 may be disposed on the substrate 100, and the LED chip 200 and the light exit surface adjuster 300 may be disposed inside the molding frame 400. In a vertical structure (e.g., taken up and down in the cross-sectional view of FIG. 2), the LED chip 200 may be mounted on the substrate 100, and the light-transmitting surface 310 of the light exit surface adjuster 300 may be disposed above the LED chip 200. The molding frame 400 may be disposed to surround the light-blocking surface 320 of the light exit surface adjuster 300, such as in the top plan view. Therefore, the light-transmitting surface 310 may be disposed in the cavity 450 without being covered by the molding frame 400.

The molding frame 400 may include a light-reflecting material. Since the cavity 450 is defined in the molding frame 400 disposed above the substrate 100, light emitted from the light-transmitting surface 310 may travel through and to above the cavity 450. Specifically, light emitted perpendicularly from the light-transmitting surface 310 may travel upward to exit the LED package 1000 via the cavity 450, and light travelling toward the molding frame 400 may be reflected by the light-reflecting material of the molding frame 400 to finally exit the LED package 1000.

The molding frame 400 may include a light-reflecting material, or may include a reflective film attached to or a light-reflective material coated on the inside of the cavity 450 at sidewalls of a base of molding frame 400. Accordingly, light emerging from the light-transmitting surface 310 can be directed upward by the molding frame 400.

Referring to FIG. 2, an encapsulant 500 may be included in the cavity 450 of the LED package 1000. The encapsulant 500 may fill the cavity 450 to seal the LED chip 200 and the light-transmitting surface 310 of the light exit surface adjuster 300 in the cavity 450. The encapsulant 500 may reduce or effectively prevent external air or moisture from reaching and thus corroding or damaging the LED chip 200, the lead frames 50, etc. The encapsulant 500 may also fix elements located within the cavity 450.

The encapsulant 500 may include a fluorescent material. The fluorescent material may include, but is not limited to, a red phosphor, green phosphor or yellow phosphor. In addition, the fluorescent material may include, but is not limited to, yttrium aluminum garnet (“YAG”), terbium aluminum garnet (“TAG”), silicate, nitride or oxynitride material.

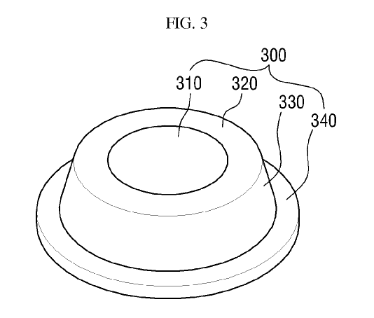

Referring to FIG. 3, the light exit surface adjuster 300 may include the light-transmitting surface 310 through which transmits light, and the light-blocking surface 320 which is located around the light-transmitting surface 310 and blocks light. The light-transmitting surface 310 and the light-blocking surface 320 may be in contact with each other.

The light exit surface adjuster 300 may further include a support 300 which extends to be bent from a rim or edge of the light-blocking surface 320. In other words, the support 330 may bend from an outer rim of the light-blocking surface 320 which does not contact the light-transmitting surface 310. The support 330 may bend toward the substrate 100 in the LED package 1000. The support 330 may separate the light-transmitting surface 310 and the light-blocking surface 320 of the light exit surface adjuster 300 from the LED chip 200. In addition, the support 300 may contact the substrate 100. Since the support 300 contacts the substrate 100 at locations where the LED chip 200 and the lead frames 50 are not formed, the LED chip 200 may not be damaged by the support 330.

The light-transmitting surface 310 and the light-blocking surface 320 may be disposed to contact the LED chip 200. However, external impact on the LED package 1000 can break the lead frames 50 and change the position of the LED chip 200. Therefore, the light-transmitting surface 310 and the light-blocking surface 320 may be separated by a predetermined distance by the support 330 in order to reduce or effectively prevent the damage to the LED package 1000 by external impact.

A support surface portion 340 may be disposed to help the support 330 be stably placed on the substrate 100. For convenience of description, support surface portion may be otherwise referred to as a support surface. The support surface 340 may contact the support 330. The support surface 340 may be disposed parallel to the substrate 100 so as to ensure a relatively wide contact area between the support surface 340 and the substrate 100. Each of the support 330 and the support surface 340 may have similar planar shape as the light-blocking surface 320, in the top plan view. In an exemplary embodiment, for example, each of the support 330 and the support surface 340 may have a circular planar shape as illustrated in FIG. 3.

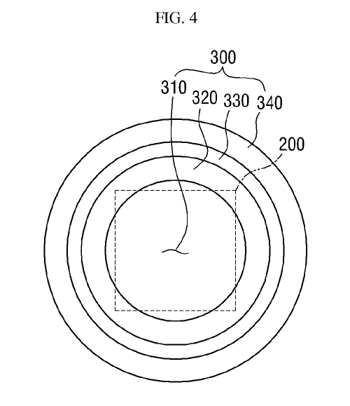

Referring to FIG. 4, the overlap area between a surface such as a light emitting surface of the LED chip 200 and the light-transmitting surface 310 may be smaller than a total area of the LED chip 200 in the top plan view. The LED chip 200 may generally have a square planar shape in the top plan view. Since light is emitted from all parts of the square LED chip 200, light may also be emitted through the light emitting surface at corners of the square LED chip 200. If light is emitted from the corners of the LED chip 200, light observed above the LED package 1000 may have a large difference between bright and dark portions due to an optical path difference.

However, if the overlap area between the LED chip 200 and the light-transmitting surface 310 is smaller than the overall surface of the LED chip 200 as in the exemplary embodiment of the invention, light emitted from the corners of the square LED chip 200 can be blocked. In the top plan view of FIG. 4, the corners of the LED chip 200 are overlapped by portions of the light-blocking surface 320. Accordingly, the planar shape of light emitted from the LED package 1000 can be changed, and the difference between bright and dark portions of the emitted light can be reduced. Consequently, uniform light can be emitted.

Part of the light-blocking surface 320 may overlap part of the LED chip 200. In addition, the light-transmitting surface 310 may include a curved planar shape in the top plan view. Referring to FIG. 4, the light-transmitting surface 310 includes a curved planar shape and overlaps the LED chip 200. Therefore, upward travel of light emitted from the corners of the LED chip 200 can be reduced or effectively prevented. In addition, the light-blocking surface 320 may preferably include a curved planar shape and a circular planar shape and block light emitted from the four corners of the LED chip 20 in equal proportions.

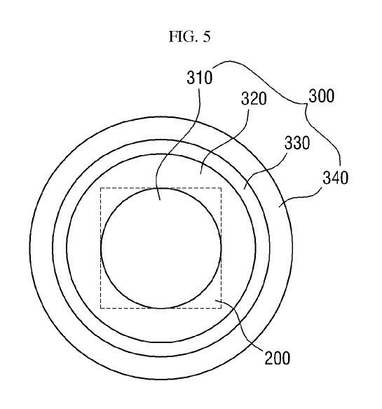

FIG. 5 is a plan view of a modified exemplary embodiment of the light exit surface adjuster 300 of FIG. 3 for which a light-transmitting surface 310 has been adjusted in size. Referring to FIG. 5, the light-transmitting surface 310 may overlap the surface of the LED chip 200 to be inscribed within the shape (e.g., edges or outline) of the LED chip 200, in the top plan view. Since the circular light-transmitting surface 310 is inscribed in the surface of the LED chip 200, the planar shape of light emitted from the LED chip 200 can be effectively changed to a circular planar shape, and light emitted from the corners of the LED chip 200 can be blocked. In addition, since the circular light-transmitting surface 310 is inscribed in the surface of the LED chip 200, the largest possible light-emitting surface that can be formed by the LED chip 200 can be defined, and light having a circular planar shape can be emitted from the LED package.

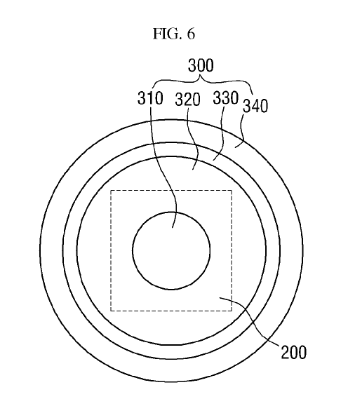

FIG. 6 is a plan view of another modified exemplary embodiment of the light exit surface adjuster 300 of FIG. 3 for which a light-transmitting surface 310 has been adjusted in size. Referring to FIG. 6, the light-transmitting surface 310 may include a circular shape and overlap the surface of the LED chip 200 to be totally included within and spaced apart from the shape (e.g., edges) of the LED chip 200, in the top plan view.

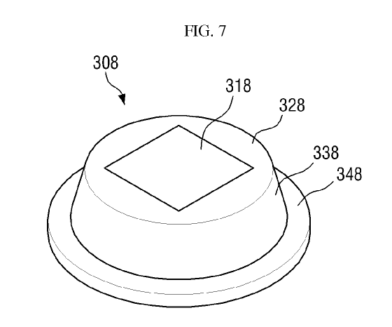

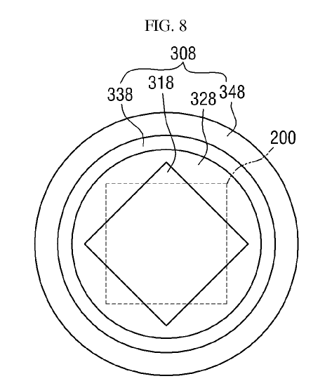

FIG. 7 illustrates another exemplary embodiment of a light exit surface adjuster 308 according to the invention. Referring to FIG. 7, a light-transmitting surface 318 may have a square planar shape. FIG. 8 is a top plan view of the light exit surface adjuster 308 of FIG. 7 with reference to an LED chip therebelow.

The light exit surface adjuster 308 may include the light-transmitting surface portion 318 through which transmits light, a light-blocking surface portion 328 which is located around the light-transmitting surface portion 318 and blocks light, a support 338 which extends to be bent from a rim or edge of the light-blocking surface 328 and a support surface portion 348 to help the support 338 to be stably placed on the substrate of the LED package.

Referring to FIG. 8, the square light-transmitting surface 318 may be disposed above and not aligned with the square shape of the LED chip 200. Therefore, light emitted from corners of the LED chip 200 can be blocked. An overlap area between the LED chip 200 and the light-transmitting surface 318 may also have corners. However, since an angle formed by each corner of the overlap area is larger than an angle formed by each corner of the LED chip 200, more uniform light than light emitted from the LED chip 200 can be emitted to the outside.

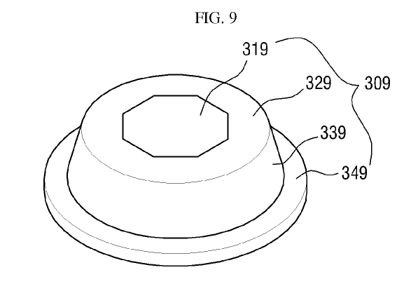

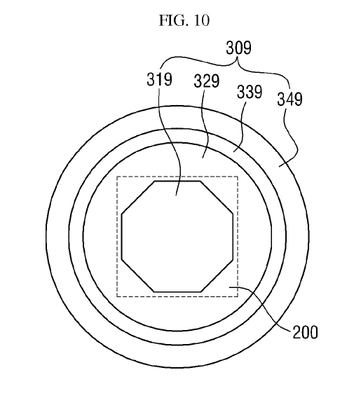

FIGS. 9 and 10 illustrate still another exemplary embodiment of a light exit surface adjuster 309 according to the invention.

The light exit surface adjuster 309 may include the light-transmitting surface portion 319 through which transmits light, a light-blocking surface portion 329 which is located around the light-transmitting surface portion 319 and blocks light, a support 339 which extends to be bent from a rim or edge of the light-blocking surface 329 and a support surface portion 349 to help the support 339 to be stably placed on the substrate of the LED package.

Referring to FIGS. 9 and 10, a light-transmitting surface 319 may have a hexagonal planar shape. The hexagonal light-transmitting surface 319 may be included inside the shape of the LED chip 200 as illustrated in FIG. 10, and an angle formed by each corner of an overlap area between the hexagonal light-transmitting surface 319 and the LED chip 200 may be larger than an angle formed by each corner of the LED chip 200 as described above with reference to FIGS. 7 and 8. Therefore, more uniform light than light emitted from the LED chip 200 can be emitted to the outside.

The above-described planar shapes of the light-transmitting surface are merely examples, and the planar shape of the light-transmitting surface may be varied.

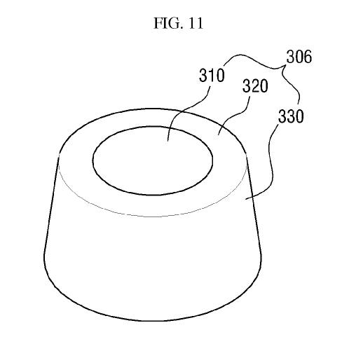

Referring to FIG. 11, a light exit surface adjuster 306 is substantially similar to that I FIG. 3, but may not include the support surface 340. In an exemplary embodiment, for example, the light exit surface adjuster 306 may be shaped like a cylinder which has a smaller diameter at an upper portion thereof than at a lower (base) portion thereof. That is, the cylinder tapers toward the top. A portion of the cylinder in which a light-transmitting surface 310 is disposed may include a light-transmitting material, and the inside of the cylinder may be hollow.

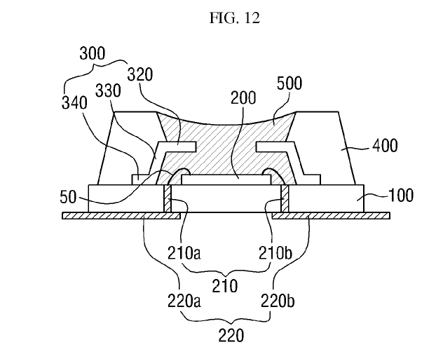

FIGS. 12 through 17 are cross-sectional views of other exemplary embodiments of an LED package according to the invention.

FIG. 12 illustrates another exemplary embodiment of an LED package according to the invention. Referring to FIG. 12, a light-transmitting surface portion may be defined as an empty space. Therefore, an encapsulant 500 may be disposed both inside and outside a light exit surface adjuster 300. Other elements of the LED package are the same as those of FIG. 2 except that the light-transmitting surface portion is defined as an empty space, and thus a detailed description thereof will be omitted.

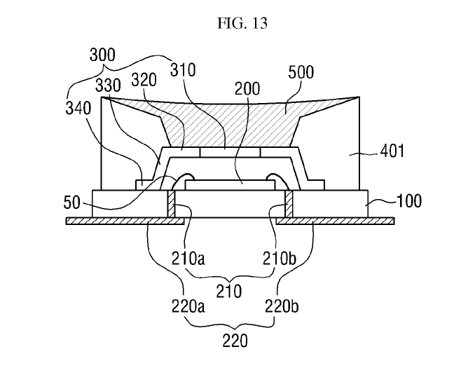

FIG. 13 illustrates another exemplary embodiment of an LED package according to the invention. Referring to FIG. 13, the inside of a molding frame 401 which defines the cavity 450 may have different slopes. The inside of the molding frame 401 may slope more steeply (larger slope with respect to the upper surface of the substrate 100) as the distance to a substrate 100 decreases as illustrated in FIG. 13 or, although not illustrated in the drawings, may slope more gently (smaller slope with respect to the upper surface of substrate 100) as the distance to the substrate 100 decreases different from the illustration of FIG. 13. If the inside of the molding frame 401 slopes as illustrated in FIG. 13, a wide distribution of light may emerge from the LED package. In contrast, the sloping inside of the molding frame 401 may increase reflectivity inside the molding frame 401. Therefore, a narrow distribution of light having high luminance light may emerge from LED package.

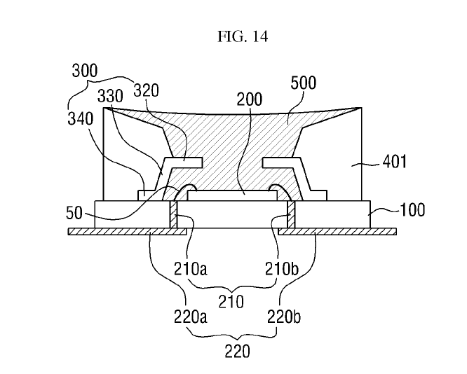

Referring to FIG. 14, the inside of a molding frame 401 which defines the cavity 450 may have different slopes and a light-transmitting surface 310 of a light exit surface adjuster 300 included in the LED package of FIG. 13 may be defined as an empty space. An encapsulant 500 may be included both inside and outside the light exit surface adjuster 300 as described above.

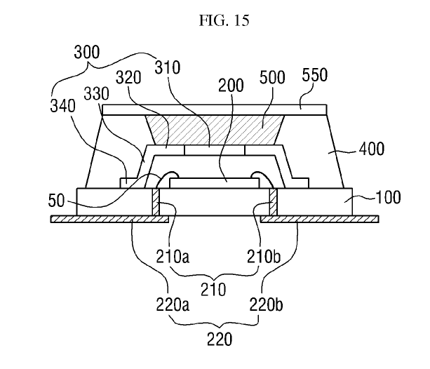

Referring to FIG. 15, a phosphor film 550 may be additionally provided on a molding frame 400. The phosphor film 550 may increase the luminance of light emitted from the LED chip 200.

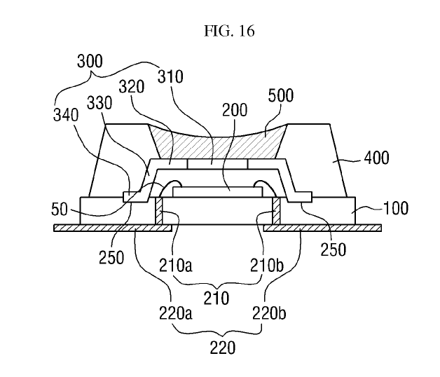

Referring to FIG. 16, a substrate 100 may further include a groove 250 defined in a portion thereof which contacts a support 330 of a light exit surface adjuster 300. Therefore, the support 330 may be inserted and coupled into the groove 250. The groove 250 may couple or fix the light exit surface adjuster 300 and the substrate 100 or may guide the light exit surface adjuster 300 to be placed at an exact position with respect to the substrate 100. Furthermore, the shape of the groove 250 on the substrate 100 may correspond to the shape of a support surface 340 connected to the support 330.

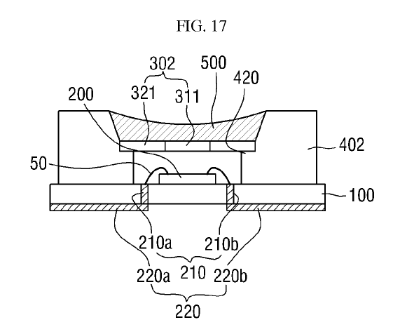

Referring to FIG. 17, a molding frame 402 may further include a step 420 defined at an inner side surface thereof which forms a cavity. A light exit surface adjuster 302 may be placed on the step 420. That is, a light-blocking surface 321 of the light exit surface adjuster 302 may be supported by and placed on the step 420.

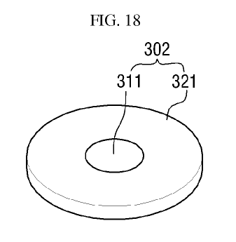

The light exit surface adjuster 302 of FIG. 17 may include only of a light-transmitting surface 311 and the light-blocking surface 321 as illustrated in FIG. 18. The light-transmitting surface 311 and the light-blocking surface 321 may lie in the same plane in the shape of, e.g., a disk.

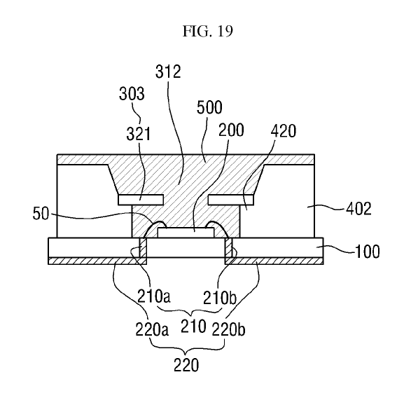

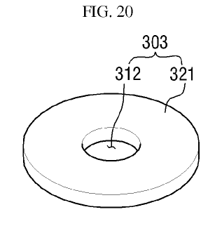

Referring to FIG. 19, a light-transmitting surface portion 312 may be defined as an empty space defined in the light exit surface adjuster 303. The light-transmitting surface portion 312 may have a circular planar shape in the top plan view, but is not limited thereto. The empty space may allow an encapsulant 500 to be included also between a light exit surface adjuster 303 and a substrate 100. An LED package of FIG. 19 may use a light exit surface adjuster 303 shown in FIG. 20, but is not limited thereto.

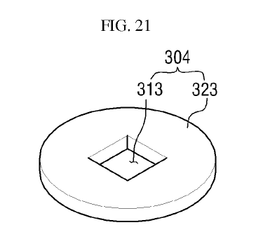

The light exit surface adjuster in FIG. 19, which is placed on a step 420, may also be a light exit surface adjuster 304 having a square light-transmitting surface portion 313 as illustrated in FIG. 21. The light-transmitting surface 313 and the light-blocking surface 323 may lie in the same plane in the shape of, e.g., a disk.

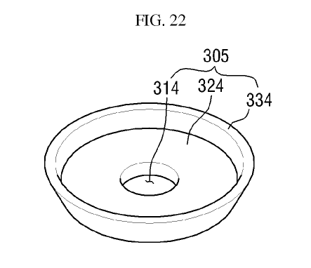

A light-transmitting surface and a light-blocking surface may not necessarily lie in the same plane as in the light exit surface adjusters of FIGS. 18, 20 and 21. In an exemplary embodiment, for example, a protruding portion 334 extending in a direction away from a substrate of an LED package may be disposed as in a light exit surface adjuster 305 of FIG. 22, or the light exit surface adjuster 300 of FIG. 3 may be used. That is, the shape of a light exit surface adjuster is not limited to a particular shape.

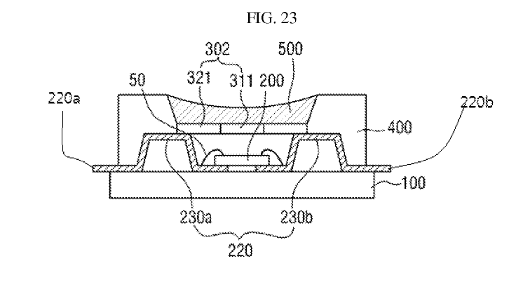

The protruding portion 334 may form a portion of a light-blocking surface including the light-blocking surface portion 324 and the protruding portion 335. The light-blocking surface portion 324 surrounds the light-emitting surface portion 314. FIG. 23 illustrates still another exemplary embodiment of an LED package according to the invention. Referring to FIG. 23, the LED package may include a first electrode 220a and a second electrode 220b which are electrically connected to an LED chip 200 and face each other with respect to the LED chip 200. The first electrode 220a and the second electrode 220b may be placed on a substrate 100, and the LED chip 200 may be placed on facing ends of the first electrode 220a and the second electrode 220b. In addition, the first electrode 220a and the second electrode 220b may respectively include a first protruding surface 230a and a second protruding surface 230b which protrude upward from the substrate 100 in the cross-sectional view. A light exit surface adjuster 302 may be placed on the first protruding surface 230a and the second protruding surface 230b.

More specifically, a light-blocking surface 321 of the light exit surface adjuster 302 may be placed on the first protruding surface 230a and the second protruding surface 230b which protrude upward from the substrate 100. Since the light exit surface adjuster 302 is placed on the first protruding surface 230a and the second protruding surface 230b, the LED chip 200 and the light exit surface adjuster 302 may be separated from each other in the cross-sectional thickness direction of the LED package.

Although not illustrated in the drawing, the LED chip 200 may be placed not on (e.g., above) the first electrode 220a and the second electrode 220b but between the first electrode 220a and the second electrode 220b, and the substrate 100. Then, the LED chip 200 may be electrically connected to the first electrode 220a and the second electrode 220b by lead frames. Therefore, only the light exit surface adjuster 302 may be placed on (e.g., above) the first electrode 220a and the second electrode 220b.

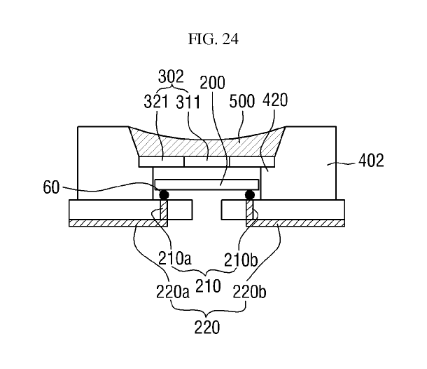

FIG. 24 illustrates still another exemplary embodiment of an LED package according to the invention. Referring to FIG. 24, an LED chip 200 and electrodes 220 may be electrically connected to each other by bumps 60 and via holes 210. Since lead frames (50 in FIG. 1) are not used, no space for the lead frames is required, and electrical disconnection due to the breaking of the lead frames can be reduced or effectively prevented.

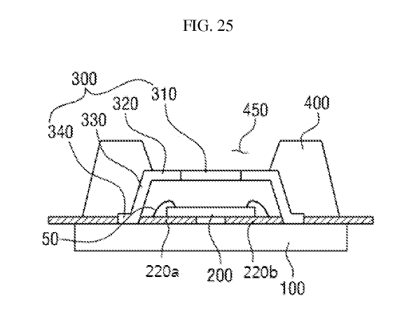

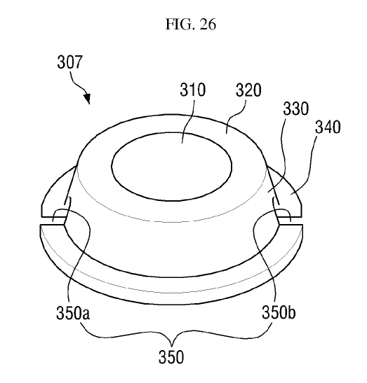

FIG. 25 illustrates still another exemplary embodiment of an LED package according to the invention. Referring to FIG. 25, electrodes 220a and 220b may be disposed on a substrate 100. Via holes may be omitted. If the electrodes 220a and 220b are disposed on the substrate 100 as illustrated in FIG. 25, a light exit surface adjuster 307 may include grooves 350, such as first and second grooves 350a and 350b, corresponding to the shapes of the electrodes 220a and 220b. Other portions of the support surface 340 excluding portions having the electrodes 220a and 220b may seal a space between a molding frame 400 and the substrate 100.

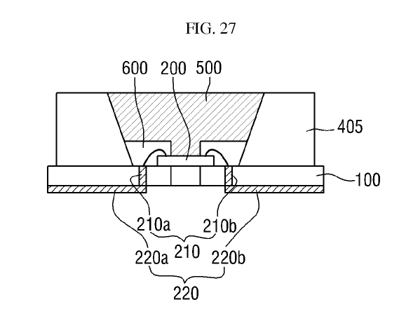

FIG. 27 illustrates still another exemplary embodiment of an LED package according to the invention. Referring to FIG. 27, the LED package may include a substrate 100, an LED chip 200 placed on the substrate 100, and a light-blocking material 600 which covers the periphery of the LED chip 200 to block a portion of light emitted from the LED chip 200. The light-blocking material 600 may be disposed in a cavity defined in the molding frame 405.

The light-blocking material 600 may be disposed to directly cover the LED chip 200 and to include. An opening may be defined in the light-blocking material 600 to have a curved planar shape in the top plan view. In addition, the light-blocking material 600 may be disposed such that the circular opening which is smaller than or equal a circle inscribed in the shape of the LED chip 200 in the top plan view.

More specifically, in an exemplary embodiment of manufacturing the LED package, the light-blocking material 600 may be formed (e.g., provided) on the LED chip 200 to contact the LED chip 200 such as by coating or covering the LED chip 200 with the light-blocking material 600. In addition, an opening may be defined on a portion of the LED chip 200 where the light-blocking material 600 is not formed, such that light can be emitted through the opening. That is, an opening may be defined using the light-blocking material 600, and the shape of a light-emitting surface of the LED chip 200 may be changed using the opening.

The light-blocking material 600 is designed to adjust the shape of the light-emitting surface of the LED chip 200. Therefore, like one or more exemplary embodiment of the light exit surface adjuster described above, the light-blocking material 600 may adjust the shape of the opening of the LED chip 200.

In an exemplary embodiment, for example, the light-blocking material 600 may be disposed to block light emitted from corners of the LED chip 200 and/or to have an opening defined therein and having a curved planar shape in the top plan view. The opening defined in the light-blocking material 600 may be disposed to be inscribed in the shape of the LED chip 200 in the top plan view. In addition, the opening defined in the light-blocking material 600 may be disposed to have a circular shape which is smaller than or equal a circle inscribed in the shape of the LED chip 200 in the top plan view.

One or more exemplary embodiment of the invention provides at least one of the following advantages.

It is possible to reduce a difference between bright and dark portions of light emitted from an LED package.

In addition, it is possible to improve poor appearance that may be caused when two LED chips, if used in an LED package, are seen.

While the invention has been particularly shown and described with reference to exemplary embodiments thereof, it will be understood by those of ordinary skill in the art that various changes in form and details may be made therein without departing from the spirit and scope of the invention as defined by the following claims. It is therefore desired that the exemplary embodiments be considered in all respects as illustrative and not restrictive, reference being made to the appended claims rather than the foregoing description to indicate the scope of the invention.

What is claimed is:

1. A light-emitting diode package comprising:
a substrate;
a light-emitting diode chip on the substrate; and
a light exit surface adjuster comprising:
a light-transmitting surface which transmits light, and
a light-blocking surface which is around the light-transmitting surface and blocks the light,
wherein
the light-emitting diode chip is between the light exit surface adjuster and the substrate, and
an overlap area between the light-emitting diode chip and the light-transmitting surface is smaller than a total area of the light-emitting diode chip, in a plan view.

2. The light-emitting diode package of claim 1, wherein the light-transmitting surface comprises a curved planar shape in the plan view.

3. The light-emitting diode package of claim 2, wherein the light-transmitting surface comprises a circular planar shape in the plan view.

4. The light-emitting diode package of claim 3, wherein the light-transmitting surface overlaps the light-emitting diode chip and is inscribed within edges of the light-emitting diode chip in the plan view.

5. The light-emitting diode package of claim 3, wherein the light transmitting surface overlaps the light-emitting diode chip and is within and spaced apart from edges of the light-emitting diode chip in the plan view.

6. The light-emitting diode package of claim 1, wherein the light exit surface adjuster further comprises a support which contacts the light-blocking surface and extends from and edge of the light-blocking surface and toward the substrate,
wherein the support separates the light-transmitting surface and the light-blocking surface from the light-emitting diode chip.

7. The light-emitting diode package of claim 6, wherein a groove is defined in the substrate and at a portion thereof which contacts the support of the light exit surface adjuster,
wherein the support extends into and is coupled to the groove.

8. The light-emitting diode package of claim 1, further comprising a frame which is on the substrate and surrounds the light-blocking surface,
wherein a cavity is defined in the frame and is open at an upper side of the frame.

9. The light-emitting diode package of claim 8, further comprising an encapsulant which fills the cavity and seals the light-emitting diode chip and the light-transmitting surface in the cavity.

10. The light-emitting diode package of claim 8, wherein the frame comprises a reflective material.

11. The light-emitting diode package of claim 1, further comprising a frame which is on the substrate, and a cavity which is defined in the frame and open at an upper side of the frame,
wherein
the light-emitting diode chip is inside the cavity, and
the frame comprises a step at an inner side surface thereof, which defines the cavity.

12. The light-emitting diode package of claim 11, wherein the light exit surface adjuster is on the step of the frame.

13. The light-emitting diode package of claim 1, further comprising a first electrode and a second electrode which are electrically connected to the light-emitting diode chip and face each other with respect to the light-emitting diode chip,
wherein
the first electrode and the second electrode are on the substrate,
the light-emitting diode chip is on the first electrode and the second electrode,
the first electrode and the second electrode respectively comprise a first protruding surface and a second protruding surface which protrude upward from the substrate, and
the light exit surface adjuster is on the first protruding surface and the second protruding surface.

14. A light-emitting diode package comprising:
a substrate;
a light-emitting diode chip on the substrate; and
a light exit surface adjuster comprising:
a light-transmitting surface which transmits light, and
a light-blocking surface which is around the light-transmitting surface and blocks the light,
wherein
the light-emitting diode chip is between the light exit surface adjuster and the substrate, and
the light-blocking surface of the light exit surface adjuster overlaps the light-emitting diode chip, in a plan view.

15. The light-emitting diode package of claim 14, wherein the light-transmitting surface comprises a circular planar shape in the plan view.

16. The light-emitting diode package of claim 15, wherein the light-transmitting surface overlaps the light-emitting diode chip and is inscribed within edges of the light-emitting diode chip in the plan view.

17. A light-emitting diode package comprising:
a substrate;
a light-emitting diode chip on the substrate; and
a light-blocking material which covers the periphery of the light-emitting diode chip and blocks light emitted from the light-emitting diode chip.

18. The light-emitting diode package of claim 17, wherein the light-blocking material covers corners of the light-emitting diode chip, in a plan view.

19. The light-emitting diode package of claim 17, wherein an opening is defined in the light-blocking material and has a curved planar shape in a plan view.

20. The light-emitting diode package of claim 19, wherein a circular opening is defined in the light-blocking material and has a size which is smaller than or equal a circle inscribed in the light-emitting diode chip in the plan view.
